(19) United States
(12) Patent Application Publication
(10) Pub. No.: US 2012/0184231 A1
(43) Pub. Date: Jul. 19, 2012

(54) WIRELESS COMMUNICATIONS USING MULTI-BANDPASS TRANSMISSION LINE WITH SLOT RING RESONATORS ON THE GROUND PLANE

(75) Inventors: Dajun CHENG, Nepean (CA); Nitin Shali, Kanata (CA); Raman Sharma, Nepean (CA)

(73) Assignee: Research In Motion Limited, Waterloo (CA)

(21) Appl. No.: 13/009,149

(22) Filed: Jan. 19, 2011

(51) Int. Cl. H04B 1/04; H05K 3/00; H01P 1/203

(52) U.S. Cl. 455/129; 333/204; 29/829

(57) ABSTRACT

The mobile wireless communications device includes a printed circuit board (PCB), wireless transceiver circuitry carried by the PCB and operating on a plurality of frequency bands, at least one antenna, and a multi-bandpass transmission line coupling the wireless transceiver circuitry to the at least one antenna. The multi-bandpass transmission line includes an electrically conductive trace on a surface of the PCB defining a transmission line signal path, and an electrically conductive layer on an opposite surface of the PCB and defining a ground plane. The electrically conductive layer has at least one set of slot rings therein and defining a plurality of slot ring resonators being electromagnetically coupled to the transmission line signal path and operable at the plurality of frequency bands.

### TECHNICAL FIELD

The present disclosure relates to the field of communications, and, more particularly, to mobile wireless communications and related methods.

### BACKGROUND

In the recent fast-developing smartphone industry, multi-radio functionality has become a desired feature to support multi-band radio (e.g. CDMA/GSM Cell band and PCS band), GPS, UMTS, Bluetooth, WiFi, etc. Multi-band components, such as a duplexer, diplexer, tri-plexer, and switches, have been widely used to meet the co-existence requirements of multi-band radio operation, such as out-of-band noise floor and spur, and antenna isolation.

It may be desired to suppress out-of-band emission levels. A typical way to achieve this is to use filters. However, the introduction of a filter would add to the amount of material and associated cost in addition to adding further insertion losses.

Conventional approaches to avoid the use of filter components may include the use of split ring resonators (SRRs) or complementary split ring resonators (CSRRs) such as described in the article “A Novel Wideband Bandpass Filter Based On Complementary Split-Ring Resonator” by X. Lai et al., PIERS, Vol. 1, 177-184, 2008. Also, the article “A New Type of Microstrip Coupler with Complementary Split-Ring Resonator (CSRR)” by K. Y. Liu et al., PIERS Online, VOL. 3, Nov. 5, 2007, discusses characteristic impedance of the even mode that can be enhanced by etching a CSRR structure in the ground plane of a microstrip double-line coupler. The equivalent circuit of the filters found in the prior art are of slots for inductance (L) and the coupling between slots for capacitance (C). Such approaches are typically directed to single band operation.

For example, U.S. Patent Application Publication No. 2007/0262834 to Albacete et al. is directed to a bandpass filter including a transmission line. A bandpass filter cell, includes a split-ring resonator, inductive element and capacitive element. The bandpass filter has a frequency response in which at least one passband can be identified. The conductor strip, split-ring resonator, inductive element and capacitive element are dimensioned and arranged so that the bandpass filter, for frequencies within the passband, behaves as a left-handed transmission line for at least one range of frequencies within the passband, and as a right-handed transmission line for at least another range of frequencies within the passband.

It may be desired to have an architecture of a multi-bandpass transmission line for use with commonly used printed circuit board (PCB), and has multi-bandpass characteristics without introducing considerable area and trace loss.

### BRIEF DESCRIPTION OF THE DRAWINGS

FIGS. 1A-1C are schematic diagrams illustrating an embodiment of a multi-bandpass transmission line and associated slot ring resonators.

FIG. 2 is schematic circuit diagram illustrating an equivalent circuit to the embodiment of the multi-bandpass transmission line and associated slot ring resonators of FIG. 1.

FIG. 3 is a graph illustrating example transmission line characteristics of the embodiment of the multi-bandpass transmission line and associated slot ring resonators of FIG. 1.

FIGS. 4A-4C are schematic diagrams illustrating another embodiment of a multi-bandpass transmission line and associated slot ring resonators.

FIGS. 5A-5C are schematic diagrams illustrating another embodiment of a multi-bandpass transmission line and associated slot ring resonators.

FIGS. 6A-6D are schematic diagrams illustrating another embodiment of a multi-bandpass transmission line and associated slot ring resonators.

FIG. 7 is a schematic block diagram illustrating a multi-band wireless communication device using a multi-bandpass transmission line and associated slot ring resonators in accordance with FIGS. 1 and 4-7.

FIG. 8 is a schematic block diagram illustrating example components that may be used with the mobile wireless communications devices of FIGS. 1 and 4-7.

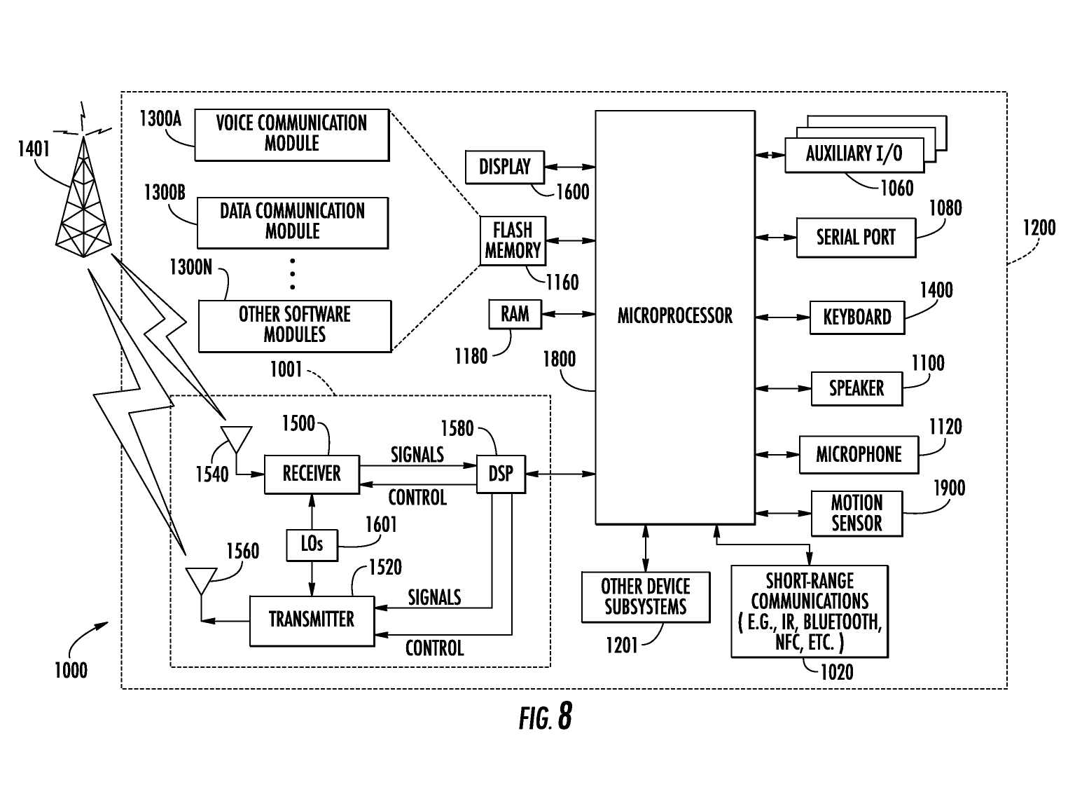

### DETAILED DESCRIPTION

The present invention will now be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

Generally, an aspect of the present embodiments is directed to a mobile wireless communications device comprising a printed circuit board (PCB), wireless transceiver circuitry carried by the PCB and operating on a plurality of frequency bands, at least one antenna, and a multi-bandpass transmission line coupling the wireless transceiver circuitry to the at least one antenna. The multi-bandpass transmission line comprising an electrically conductive trace on a surface of the PCB defining a transmission line signal path, and an electrically conductive layer on an opposite surface of said PCB and defining a ground plane. The electrically conductive layer having at least one set of slot rings therein and defining a plurality of slot ring resonators being electromagnetically coupled to the transmission line signal path and operable at the plurality of frequency bands.

The at least one set of slot rings may comprise a set of concentric slot rings, and/or each slot ring may comprise a continuous slot ring. Each slot ring of a given set of slot rings may define a respective resonant frequency within a given frequency band.

A pair of electrically conductive traces may be on opposite lateral sides of the transmission line signal path. Also, a dielectric layer may be over the surface of the PCB and covering the electrically conductive trace. A second electrically conductive layer may be on the dielectric layer and defining a second ground plane, and a second electrically conductive layer having at least one set of slot rings therein and defining a plurality of slot ring resonators may be electromagnetically coupled to the transmission line signal path and operable at the plurality of frequency bands.

The at least one set of slot rings may comprise polygonal-shaped slot rings or circular-shaped slot rings, for example. The plurality of slot ring resonators may be aligned with the transmission line signal path at the plurality of frequency bands.

Another aspect of the present embodiments is directed to a related multi-bandpass transmission line and communication method.

The proposed embodiments may differ from conventional approaches by the use of a slot ring for each resonant frequency, each slot ring can be considered as an LC resonator, and by employing concentric slot ring resonators for multiple bandpass RF characteristics, for example. The physical mechanism difference also results in the difference in equivalent circuit. Also, the present embodiments are focused on multi-band operation without increasing the physical dimensions of the embodiment. The design using conventional approaches relies on the coupling between complementary split ring resonator and hard in tuning for multi-band operation, while the proposed embodiments use a slot ring resonator (e.g. a concentric slot-ring resonator) and each slot ring resonator corresponds with one operating frequency facilitating the multi-band operation. Furthermore, a multi-band radio system architecture is also proposed that uses the present multi-bandpass transmission line approach.

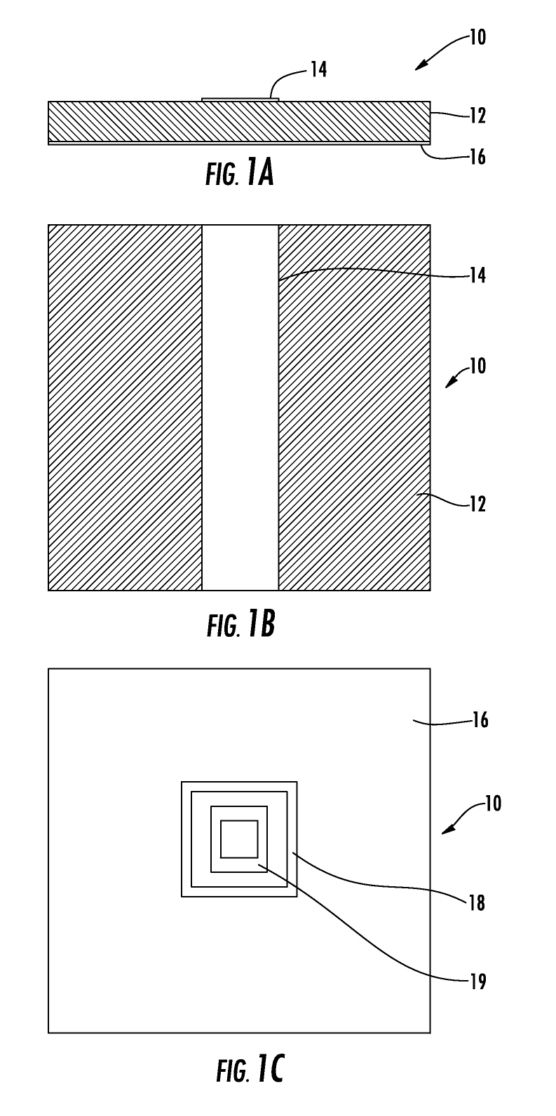

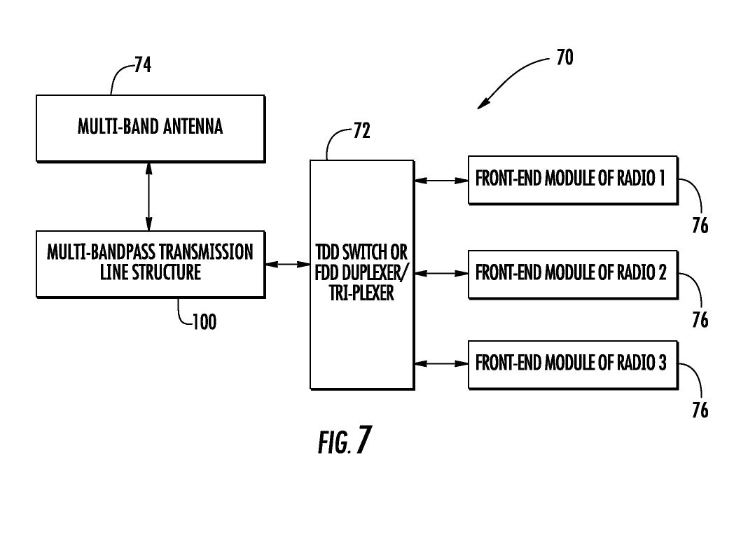

Referring initially to FIGS. 1A-1C and 7, a mobile wireless communications device 70 includes a printed circuit board (PCB) 12, wireless transceiver circuitry 72 carried by the PCB and operating on a plurality of frequency bands. For example, such wireless transceiver circuitry may include a Time Division Duplex (TDD) switch (e.g. single pull multi-throw switch) or Frequency Division Duplex (FDD) duplexer/triplexer, for example. At least one antenna 74, for example, a multi-band antenna, may be provided. A multi-bandpass transmission line structure 100 (FIG. 7) couples the wireless transceiver circuitry 72 to the antenna 74.

Referring more specifically to FIGS. 1A-1C, an embodiment of the multi-bandpass transmission line 10 will be described. A cross-sectional view of the multi-bandpass transmission line 10 is shown in FIG. 1A, a top view is shown in FIG. 1B, and a bottom view is shown in FIG. 1C. An electrically conductive trace is on a surface of the PCB 12, or dielectric substrate, an defines a transmission line signal path 14. An electrically conductive layer is on an opposite surface of said PCB 12 and defines a ground plane 16. The ground plane 16 has at least one set of slot rings 18 therein and defines a plurality of slot ring resonators 19 being electromagnetically coupled to the transmission line signal path 14 and operable at the plurality of frequency bands.

The multi-bandpass transmission line 10 with slot ring resonators 19 etched in the ground plane 16 in accordance with features of the present embodiments may provide an approach to attenuate unwanted signals with little or no extra introduction of insertion loss for the wanted signals, while reducing materials cost, meeting the regulatory emission requirements, and supporting simultaneous multi-radio operation.

The multi-bandpass transmission line 10 may use concentric slot ring resonators 19 on the ground plane. Such concentric rings are designed to share the center point such that the desired multi-band resonance can be achieved at the same time through the electromagnetic coupling between the rings 18 and the transmission line signal path 14. The dimensions of the rings 18 depend on the ground plane substrate parameters (e.g., thickness, dielectric constant) and the desired operating frequency. For a typical FR-4 substrate, the estimated dimensions of the slot ring resonators may be 3.5 mm for cell band (850 MHz), 2.7 mm for PCS band (1800-1900 MHz), 2.4 mm for 2100 MHz band, and 2 mm for 2400 MHz ISM band.

Different embodiments are set forth herein. In various embodiments the concentric rings may have a circular shape, for example, implemented in a coplanar waveguide transmission line. In other embodiments the concentric rings may have a square shape, for example, implemented in a microstrip transmission line. The proposed example embodiments feature flexibility in etching and placement on a mobile wireless device or handset ground plane.

Referring again to FIG. 1, the embodiment illustratively includes the multi-bandpass transmission line 14 as a microstrip transmission line. The slot ring resonators 19 are co-located in the ground plane 16, and would exhibit the multi-bandpass characteristics. In this example, there are two slot ring resonators 19, an outer one and inner one. These slot ring resonators 19 have the same geometry center point, so that the multi-band desired signals can be resonated in the same coupling spot. For example, the larger slot ring resonator has the lower resonant frequency, while the smaller slot ring resonator has the higher resonant frequency. The transmit or receive signals are electromagnetically coupled to the slot ring resonators 19 etched in the ground plane 16.

Due to the relatively thin thickness of the substrate (e.g. on the order of 50 μm), the coupling between the transmission line 14 and the slot ring resonators 19 may be strong which would result in low insertion loss of the structure. The coupling is frequency-dependent. That is, if the coupling coefficient is defined as the ratio of output power and input power of the multi-bandpass transmission line 10, it is frequency-dependent due to the frequency response of the resonators 19. Since each slot ring resonator 19 has a different resonant frequency, multi-bandpass characteristics can be achieved. Thus, the slot ring resonators 19, etched in the ground plane 16, may ensure sufficient electromagnetic coupling of multi-band desired signals, while reducing the coupling of unwanted signals in the non-desired frequency bands.

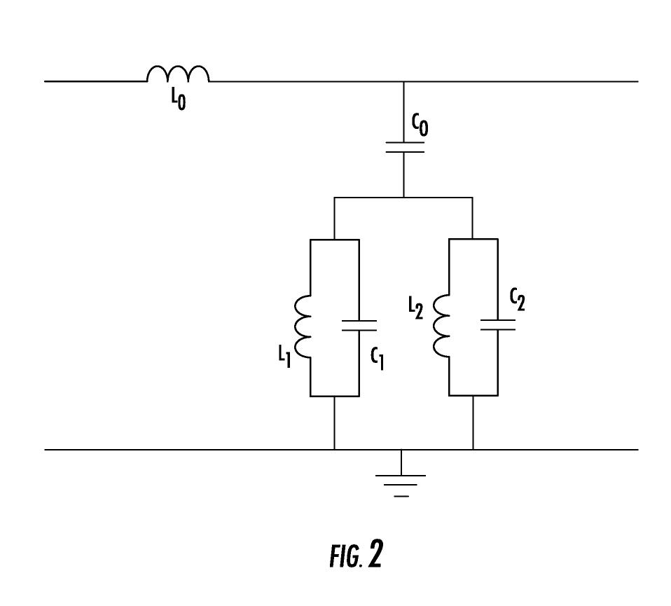

An equivalent circuit of the embodiment of FIG. 1A-1C will be described with reference to FIG. 2. The L0 and C0 are the equivalent inductance and capacitance of the transmission line, L1 and C1 are the equivalent inductance and capacitance of one slot ring resonator 19 (e.g. the outer one), L2 and C2 are the equivalent inductance and capacitance of another slot ring resonator 19 (e.g. the inner one). L1 and C1 correspond to the bandpass frequency f1, L2 and C2 correspond to the bandpass frequency f2, where f1 and f2 are the central frequencies of the wanted signal bands. The inner slot ring resonator corresponds to higher resonating frequency, the outer slot ring corresponds to the lower frequency. For example, fi=1/(2*π*√(Li*Ci)), where i=1, 2.

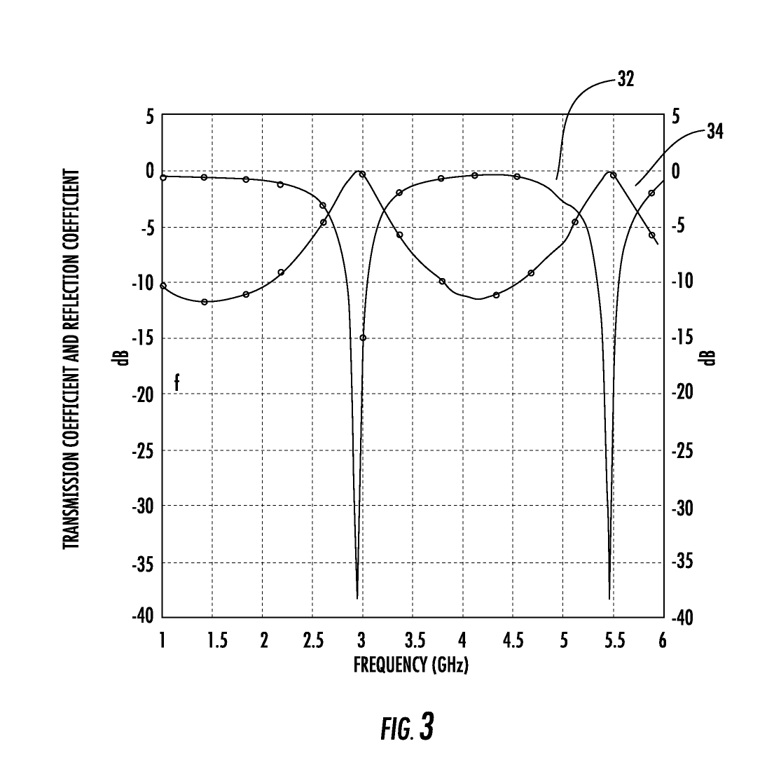

FIG. 3 is a graph illustrating example of transmission characteristics of the multi-bandpass transmission line 14 with two co-located slot ring resonators 19 in the ground plane 16. In FIG. 3, 32 represents the reflection coefficient S11, and 34 is the transmission coefficient S21. The insertion loss, as observed in 34, shows frequency dependency, and the reflection coefficient 32 also exhibits strong frequency response which is better than −25 dB. The strong frequency response of the reflection coefficient 32 is a typical illustration of the RF resonator phenomenon. It is shown that the RF signals only transmit at two wanted frequency bands with less than 0.3 dB insertion loss, and would be attenuated at unwanted frequencies.

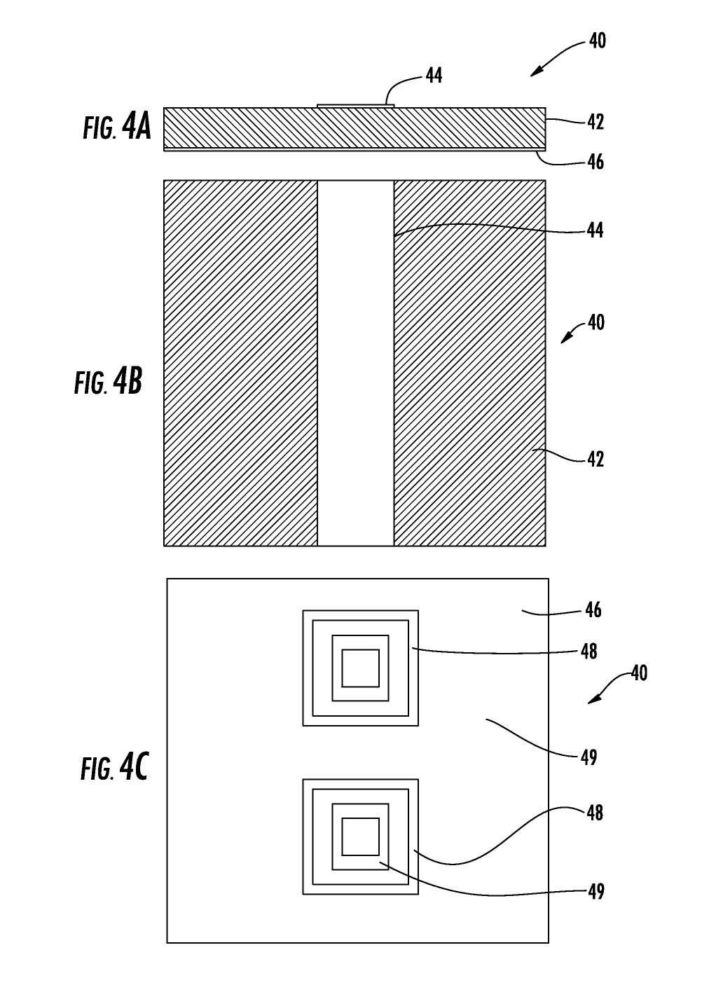

To further improve the attenuation at unwanted frequencies, a multi-stage configuration may be introduced. One embodiment of a two-stage configuration will be described with reference to FIGS. 4A-4C. A cross-sectional view of the multi-bandpass transmission line 40 is shown in FIG. 4A, a top view is shown in FIG. 4B, and a bottom view is shown in FIG. 4C. In the multi-stage configuration, each group of slot ring resonators 49, defined by the set of slot rings 48 in the ground plane 46, have the same dimension parameters but are located apart along the transmission line 44 with the PCB 42 therebetween.

The insertion loss of this embodiment could be as low as 0.3 dB, and the bandwidth of the 3 dB bandpass characteristics may be over 10% which is enough for general wireless standards (e.g., CDMA Cell band, CDMA PCS band, GSM/GPRS/EDGE 800, 900, 1800, 1900, UMTS, WiFi, Bluetooth, GPS).

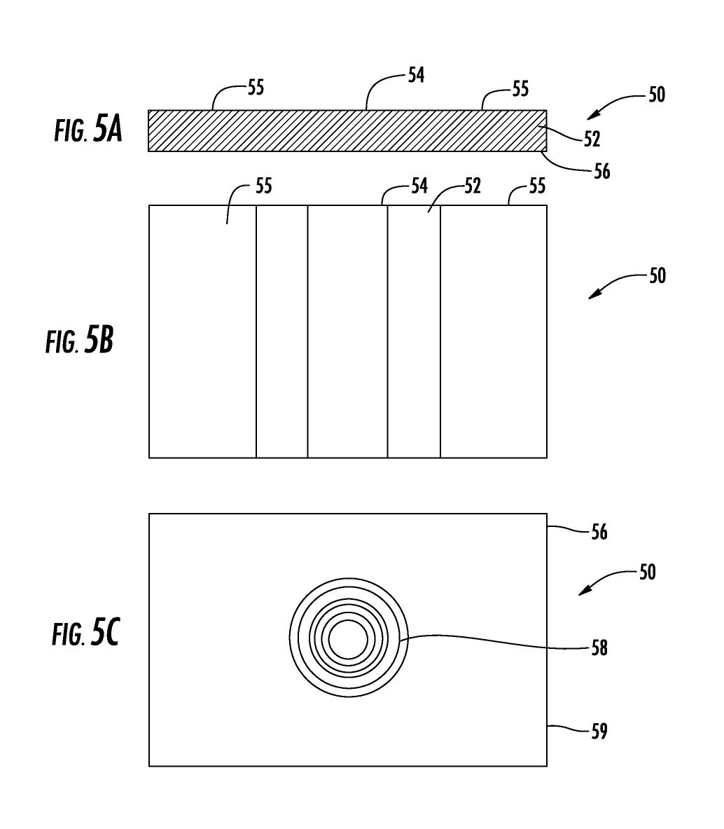

Another embodiment for a multi-bandpass coplanar waveguide transmission line is described with reference to FIGS. 5A-5C. A cross-sectional view of the multi-bandpass transmission line 50 is shown in FIG. 5A, a top view is shown in FIG. 5B, and a bottom view is shown in FIG. 5C. In the coplanar waveguide transmission line configuration, the slot ring resonators 59 are defined by the set of slot rings 58 in the ground plane 56 adjacent the transmission line 54 with the PCB 52 therebetween. The top electrically conductive trace also includes a pair of electrically conductive traces 55 on opposite lateral sides of the transmission line signal path 54. Three slot ring resonators 59 are etched in the ground plane 56 to implement tri-bandpass transmission characteristics.

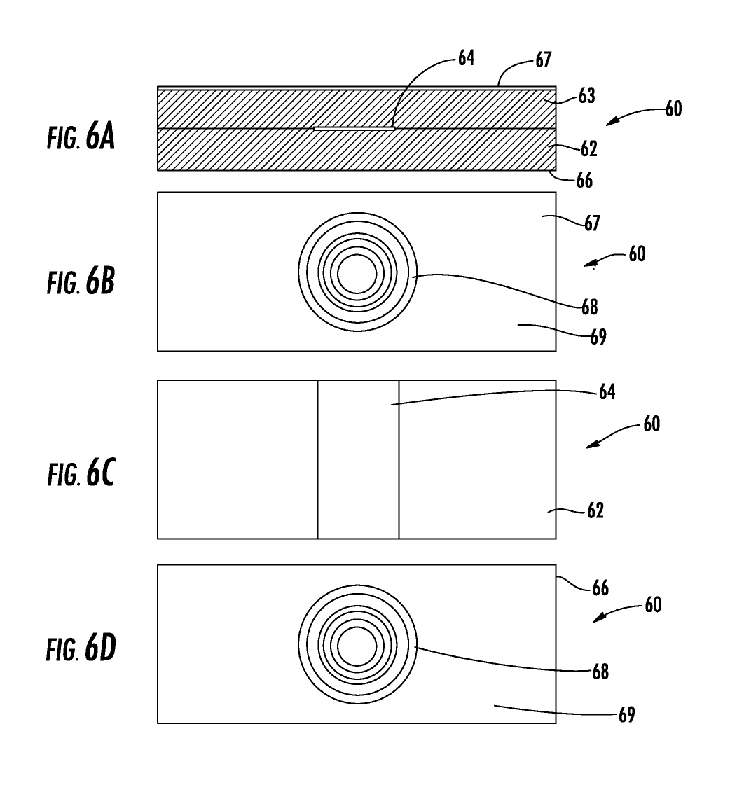

Another embodiment for a multi-bandpass stripline transmission line is described with reference to FIGS. 6A-6D. A cross-sectional view of the multi-bandpass stripline transmission line 60 is shown in FIG. 6A, a top view is shown in FIG. 6B, a top view of the uncovered stripline is shown in FIG. 6C, and a bottom view is shown in FIG. 6D. In the stripline transmission line configuration, the slot ring resonators 69 are defined by the set of slot rings 68 in the lower and upper ground planes 66/67 adjacent the stripline transmission line 64 with the PCB 62 and another dielectric layer 63 therebetween. Three slot ring resonators 69 are etched separately in the two ground planes to implement tri-bandpass transmission characteristics.

Another aspect of the present embodiments is directed to a related method. The method is for making a multi-bandpass transmission line 100, and includes forming an electrically conductive trace on a surface of the PCB 12 defining a transmission line signal path 14, and forming an electrically conductive layer on an opposite surface of the PCB 12 and defining a ground plane 16. The electrically conductive layer is formed with at least one set of slot rings 18 therein and defining a plurality of slot ring resonators 19 being electromagnetically coupled to the transmission line signal path 14 and operable at the plurality of frequency bands.

By way of example, various mobile devices that may be used for the embodiments described herein include portable or mobile telephones, smartphones, tablet computers, etc. Furthermore, control of such a device may be implemented using a combination of hardware (e.g., microprocessor, etc.) and non-transitory computer-readable medium components having computer-executable instructions for performing the various operations described herein. Moreover, although the description may refer to a mobile device, it may be stationary or otherwise intended not to be readily portable.

Example components of a mobile wireless communications device 1000 that may be used in accordance with the above-described embodiments are further described below with reference to FIG. 9. The device 1000 illustratively includes a housing 1200, a keyboard or keypad 1400 and an output device 1600. The output device shown is a display 1600, which may comprise a full graphic LCD. Other types of output devices may alternatively be utilized. A processing device 1800 is contained within the housing 1200 and is coupled between the keypad 1400 and the display 1600. The processing device 1800 controls the operation of the display 1600, as well as the overall operation of the mobile device 1000, in response to actuation of keys on the keypad 1400.

The housing 1200 may be elongated vertically, or may take on other sizes and shapes (including clamshell housing structures). The keypad may include a mode selection key, or other hardware or software for switching between text entry and telephony entry.

In addition to the processing device 1800, other parts of the mobile device 1000 are shown schematically in FIG. 9. These include a communications subsystem 1001; a short-range communications subsystem 1020; the keypad 1400 and the display 1600, along with other input/output devices 1060, 1080, 1100 and 1120; as well as memory devices 1160, 1180 and various other device subsystems 1201. The mobile device 1000 may comprise a two-way RF communications device having data and, optionally, voice communications capabilities. In addition, the mobile device 1000 may have the capability to communicate with other computer systems via the Internet.

Operating system software executed by the processing device 1800 is stored in a persistent store, such as the flash memory 1160, but may be stored in other types of memory devices, such as a read only memory (ROM) or similar storage element. In addition, system software, specific device applications, or parts thereof, may be temporarily loaded into a volatile store, such as the random access memory (RAM) 1180. Communications signals received by the mobile device may also be stored in the RAM 1180.

The processing device 1800, in addition to its operating system functions, enables execution of software applications 1300A-1300N on the device 1000. A predetermined set of applications that control basic device operations, such as data and voice communications 1300A and 1300B, may be installed on the device 1000 during manufacture. In addition, a personal information manager (PIM) application may be installed during manufacture. The PIM may be capable of organizing and managing data items, such as e-mail, calendar events, voice mails, appointments, and task items. The PIM application may also be capable of sending and receiving data items via a wireless network 1401. The PIM data items may be seamlessly integrated, synchronized and updated via the wireless network 1401 with corresponding data items stored or associated with a host computer system.

Communication functions, including data and voice communications, are performed through the communications subsystem 1001, and possibly through the short-range communications subsystem. The communications subsystem 1001 includes a receiver 1500, a transmitter 1520, and one or more antennas 1540 and 1560. In addition, the communications subsystem 1001 also includes a processing module, such as a digital signal processor (DSP) 1580, and local oscillators (LOs) 1601. The specific design and implementation of the communications subsystem 1001 is dependent upon the communications network in which the mobile device 1000 is intended to operate. For example, a mobile device 1000 may include a communications subsystem 1001 designed to operate with the Mobitex™, Data TAC™ or General Packet Radio Service (GPRS) mobile data communications networks, and also designed to operate with any of a variety of voice communications networks, such as AMPS, TDMA, CDMA, WCDMA, PCS, GSM, EDGE, etc. Other types of data and voice networks, both separate and integrated, may also be utilized with the mobile device 1000. The mobile device 1000 may also be compliant with other communications standards such as 3GSM, 3GPP, UMTS, 4G, etc.

Network access requirements vary depending upon the type of communication system. For example, in the Mobitex and DataTAC networks, mobile devices are registered on the network using a unique personal identification number or PIN associated with each device. In GPRS networks, however, network access is associated with a subscriber or user of a device. A GPRS device therefore typically involves use of a subscriber identity module, commonly referred to as a SIM card, in order to operate on a GPRS network.

When required network registration or activation procedures have been completed, the mobile device 1000 may send and receive communications signals over the communication network 1401. Signals received from the communications network 1401 by the antenna 1540 are routed to the receiver 1500, which provides for signal amplification, frequency down conversion, filtering, channel selection, etc., and may also provide analog to digital conversion. Analog-to-digital conversion of the received signal allows the DSP 1580 to perform more complex communications functions, such as demodulation and decoding. In a similar manner, signals to be transmitted to the network 1401 are processed (e.g. modulated and encoded) by the DSP 1580 and are then provided to the transmitter 1520 for digital to analog conversion, frequency up conversion, filtering, amplification and transmission to the communication network 1401 (or networks) via the antenna 1560.

In addition to processing communications signals, the DSP 1580 provides for control of the receiver 1500 and the transmitter 1520. For example, gains applied to communications signals in the receiver 1500 and transmitter 1520 may be adaptively controlled through automatic gain control algorithms implemented in the DSP 1580.

In a data communications mode, a received signal, such as a text message or web page download, is processed by the communications subsystem 1001 and is input to the processing device 1800. The received signal is then further processed by the processing device 1800 for an output to the display 1600, or alternatively to some other auxiliary I/O device 1060. A device may also be used to compose data items, such as e-mail messages, using the keypad 1400 and/or some other auxiliary I/O device 1060, such as a touchpad, a rocker switch, a thumb-wheel, or some other type of input device. The composed data items may then be transmitted over the communications network 1401 via the communications subsystem 1001.

In a voice communications mode, overall operation of the device is substantially similar to the data communications mode, except that received signals are output to a speaker 1100, and signals for transmission are generated by a microphone 1120. Alternative voice or audio I/O subsystems, such as a voice message recording subsystem, may also be implemented on the device 1000. In addition, the display 1600 may also be utilized in voice communications mode, for example to display the identity of a calling party, the duration of a voice call, or other voice call related information.

The short-range communications subsystem enables communication between the mobile device 1000 and other proximate systems or devices, which need not necessarily be similar devices. For example, the short-range communications subsystem may include an infrared device and associated circuits and components, a Bluetooth™ communications module to provide for communication with similarly-enabled systems and devices, or a near field communications (NEC) sensor for communicating with a NEC device or NEC tag via NEC communications.

Many modifications and other embodiments will come to the mind of one skilled in the art having the benefit of the teachings presented in the foregoing descriptions and the associated drawings. Therefore, it is understood that various modifications and embodiments are intended to be included within the scope of the appended claims.

That which is claimed is:

1. A mobile wireless communications device comprising:
a printed circuit board (PCB);
wireless transceiver circuitry carried by said PCB and operating on a plurality of frequency bands; at least one antenna; and
a multi-bandpass transmission line coupling said wireless transceiver circuitry to said at least one antenna and comprising
an electrically conductive trace on a surface of said PCB defining a transmission line signal path, and
an electrically conductive layer on an opposite surface of said PCB and defining a ground plane,
said electrically conductive layer having at least one set of slot rings therein and defining a plurality of slot ring resonators being electromagnetically coupled to the transmission line signal path and operable at said plurality of frequency bands.

2. The mobile wireless communications device according to claim 1 wherein said at least one set of slot rings comprises a set of concentric slot rings.

3. The mobile wireless communications device according to claim 1 wherein each slot ring comprises a continuous slot ring.

4. The mobile wireless communications device according to claim 1 wherein each slot ring of a given set of slot rings defines a respective resonant frequency within a given frequency band.

5. The mobile wireless communications device according to claim 1 further comprising a pair of electrically conductive traces on opposite lateral sides of said transmission line signal path.

6. The mobile wireless communications device according to claim 1 further comprising a dielectric layer over the surface of said PCB and covering the electrically conductive trace.

7. The mobile wireless communications device according to claim 6 further comprising:
a second electrically conductive layer on the dielectric layer and defining a second ground plane; and
a second electrically conductive layer having at least one other set of slot rings therein and defining another plurality of slot ring resonators being electromagnetically coupled to the transmission line signal path and operable at said plurality of frequency bands.

8. The mobile wireless communications device according to claim 1 wherein the at least one set of slot rings comprises polygonal-shaped slot rings.

9. The mobile wireless communications device according to claim 1 wherein the at least one set of slot rings comprises circular-shaped slot rings.

10. The mobile wireless communications device according to claim 1 wherein said plurality of slot ring resonators are aligned with the transmission line signal path at said plurality of frequency bands.

11. A multi-bandpass transmission line for use in a wireless communications device to couple wireless transceiver circuitry operating on a plurality of frequency bands to at least one antenna, the multi-bandpass transmission line comprising:
a dielectric substrate;
an electrically conductive trace on a surface of said dielectric substrate and defining a transmission line signal path; and
an electrically conductive layer on an opposite surface of said dielectric substrate and defining a ground plane;
said electrically conductive layer having at least one set of slot rings therein and defining a plurality of slot ring resonators being electromagnetically coupled to the transmission line signal path and operable at the plurality of frequency bands.

12. The multi-bandpass transmission line according to claim 11 wherein said at least one set of slot rings comprises a set of concentric slot rings.

13. The multi-bandpass transmission line according to claim 11 wherein each slot ring comprises a continuous slot ring.

14. The multi-bandpass transmission line according to claim 11 wherein each slot ring of a given set of slot rings defines a respective resonant frequency within a given frequency band.

15. The multi-bandpass transmission line according to claim 11 further comprising a pair of electrically conductive traces on opposite lateral sides of said transmission line signal path.

16. The multi-bandpass transmission line according to claim 11 further comprising:
a dielectric layer over the surface of said PCB and covering the electrically conductive trace;
a second electrically conductive layer on the dielectric layer and defining a second ground plane; and
a second electrically conductive layer having at least one other set of slot rings therein and defining another plurality of slot ring resonators being electromagnetically coupled to the transmission line signal path and operable at the plurality of frequency bands.

17. The multi-bandpass transmission line according to claim 11 wherein said plurality of slot ring resonators are aligned with the transmission line signal path at the plurality of frequency bands.

18. A method for making a multi-bandpass transmission line and comprising:
forming an electrically conductive trace on a surface of the PCB defining a transmission line signal path; and
forming an electrically conductive layer on an opposite surface of the PCB and defining a ground plane;
the electrically conductive layer having at least one set of slot rings therein and defining a plurality of slot ring resonators being electromagnetically coupled to the transmission line signal path and operable at the plurality of frequency bands.

19. The method according to claim 18 wherein the at least one set of slot rings comprises a set of concentric slot rings.

20. The method according to claim 18 wherein each slot ring comprises a continuous slot ring.

21. The method according to claim 18 wherein each slot ring of a given set of slot rings defines a respective resonant frequency within a given frequency band.

22. The method according to claim 18 further comprising forming a pair of electrically conductive traces on opposite lateral sides of the transmission line signal path.

23. The method according to claim 18 further comprising:
forming a dielectric layer over the surface of the PCB and covering the electrically conductive trace;
forming a second electrically conductive layer on the dielectric layer and defining a second ground plane; and
forming a second electrically conductive layer having at least one other set of slot rings therein and defining another plurality of slot ring resonators being electromagnetically coupled to the transmission line signal path and operable at the plurality of frequency bands.

24. The communication method according to claim 18 wherein the plurality of slot ring resonators are aligned with the transmission line signal path at the plurality of frequency bands.
